(19) United States
(12) Patent Application Publication
(10) Pub. No.: US 2025/0183219 A1
(43) Pub. Date: Jun. 5, 2025

(54) SEMICONDUCTOR PACKAGES WITH CHIP STACK

(71) Applicant: SAMSUNG ELECTRONICS CO., LTD., Suwon-si (KR)

(72) Inventors: Hyunho Chu, Suwon-si (KR); Jiwon Shin, Suwon-si (KR); Sanghyeon Lee, Suwon-si (KR)

(21) Appl. No.: 18/779,492

(22) Filed: Jul. 22, 2024

(30) Foreign Application Priority Data
Dec. 4, 2023 (KR) 10-2023-0173442

(51) Int. Cl. H01L 23/00; H01L 23/31; H01L 23/538; H01L 25/065

(52) U.S. Cl. CPC H01L 24/40; H01L 24/05; H01L 24/41; H01L 24/80; H01L 25/0657; H01L 23/3107; H01L 23/5383; H01L 24/32; H01L 24/33; H01L 24/73; H01L 2224/04034; H01L 2224/32145; H01L 2224/32225; H01L 2224/33181; H01L 2224/40145; H01L 2224/40227; H01L 2224/40499; H01L 2224/4118; H01L 2224/73263; H01L 2224/80896; H01L 2225/06565

(57) ABSTRACT

A semiconductor package and a method of manufacturing the same are provided, in which a height and a one-dimensional area of the semiconductor package may be reduced. The semiconductor package includes a package substrate, a chip stack structure including at least two semiconductor chips aligned with one another and stacked on the package substrate in a vertical direction, each of the at least two semiconductor chips including chip pads exposed at a side surface thereof, an anisotropic conductive film (ACF) covering a side surface of the chip stack structure, and a conductive pattern film covering the ACF and including a conductive pattern connecting the chip pads to a substrate pad of the package substrate.

### CROSS-REFERENCE TO RELATED APPLICATION

This application claims priority under 35 U.S.C. § 119 to Korean Patent Application No. 10-2023-0173442, filed on Dec. 4, 2023, in the Korean Intellectual Property Office, the disclosure of which is incorporated by reference herein in its entirety.

### BACKGROUND

As the electronics industry advances rapidly and the demands of users increases, electronic devices are being miniaturized further and becoming more multifunctional. As electronic devices are miniaturized and made light, semiconductor packages are being miniaturized and made light, and moreover, semiconductor packages need high performance, large capacity, and high reliability. As semiconductor packages having high performance and large capacity are implemented, the power consumption of semiconductor packages is increasing. Therefore, the structure of semiconductor packages, which corresponds to the size/performance of semiconductor packages and is for stable supply of power to a semiconductor package, is increasing in significance.

### SUMMARY

Some implementations according to this disclosure provide a semiconductor package and a method of manufacturing the same, in which a height and a one-dimensional area of the semiconductor package may be reduced.

The advantages are not limited to the foregoing, and other advantages will be clearly understood by those of ordinary skill in the art from descriptions below.

A semiconductor package according to some implementations includes a package substrate, a chip stack structure including at least two semiconductor chips aligned with one another and stacked on the package substrate in a vertical direction, each of the at least two semiconductor chips including chip pads exposed at a side surface thereof, an anisotropic conductive film (ACF) covering a side surface of the chip stack structure, and a conductive pattern film covering the ACF and including a conductive pattern connecting the chip pads to a substrate pad of the package substrate.

A semiconductor package according to some implementations includes a package substrate including a substrate pad disposed on an upper surface of an outer portion thereof, a chip stack structure including at least two semiconductor chips aligned with one another and stacked on a center portion of the package substrate in a vertical direction, each of the at least two semiconductor chips including a body layer at a lower portion thereof, an active layer at an upper portion thereof, and chip pads exposed at a side surface of the active layer, an anisotropic conductive film (ACF) covering a side surface of the chip stack structure and the substrate pad on the package substrate and including an adhesive resin and a conductive particle, and a conductive pattern film including a polymer film and a conductive pattern on the polymer film and covering the ACF so that the chip pads are connected to the substrate pad through the conductive pattern.

A semiconductor package according to some implementations includes a package substrate, a chip stack structure including at least two semiconductor chips aligned with one another and stacked on the package substrate in a vertical direction, each of the at least two semiconductor chips including chip pads exposed at four side surfaces thereof, an anisotropic conductive film (ACF) covering four side surfaces of the chip stack structure and a portion of an upper surface of the package substrate, a conductive pattern film covering the ACF and including a conductive pattern connecting the chip pads to a substrate pad of the package substrate, and a sealant covering a side surface and an upper surface of the chip stack structure, on the package substrate.

A method of manufacturing a semiconductor package according to some implementations includes preparing a plurality of semiconductor chips each including a body layer of a lower portion thereof and an active layer of an upper portion thereof and each having a structure where chip pads are exposed at a side surface of the active layer, stacking a first semiconductor chip of the plurality of semiconductor chips on a package substrate by using an adhesive layer, stacking at least one second semiconductor chip of the plurality of semiconductor chips on the first semiconductor chip to be aligned in a vertical direction to form a chip stack structure including the first semiconductor chip and the at least one second semiconductor chip, attaching an anisotropic conductive film (ACF) on at least one side surface of the chip stack structure and a partial upper surface of the package substrate, attaching a conductive pattern film including a conductive pattern on the ACF, and forming a sealant, covering a side surface and an upper surface of the chip stack structure, on the package substrate, wherein the attaching of the conductive pattern film on the ACF includes connecting the chip pads to a substrate pad of the package substrate by using the conductive pattern.

### BRIEF DESCRIPTION OF THE DRAWINGS

Implementations will be more clearly understood from the following detailed description taken in conjunction with the accompanying drawings in which:

FIG. 1 is a perspective view of a semiconductor package according to some implementations;

FIG. 2A is a cross-sectional view of a semiconductor package according to some implementations;

FIG. 2B and 2C are perspective views of a semiconductor package according to some implementations;

FIG. 2D is a plan view of a semiconductor package according to some implementations;

FIG. 3A is a perspective view of a semiconductor package according to some implementations;

FIG. 3B is a plan view of a semiconductor package according to some implementations;

FIG. 4A is a perspective view of a semiconductor package according to some implementations;

FIG. 4B is a plan view of a semiconductor package according to some implementations;

FIGS. 5A and 5B are perspective views of semiconductor packages according to some implementations;

FIGS. 6A to 6E are perspective views illustrating a process of manufacturing a semiconductor package, according to some implementations;

FIGS. 7A and 7B are plan views illustrating a process of attaching a conductive pattern film, according to some implementations;

FIGS. 8A to 8H are cross-sectional views illustrating a process of preparing a semiconductor chip, according to some implementations; and

FIGS. 9A to 9C are diagrams illustrating a process of forming an oxide bonding in a process of stacking semiconductor chips, according to some implementations.

### DETAILED DESCRIPTION

Hereinafter, examples will be described in detail with reference to the accompanying drawings. Like reference numerals refer to like elements in the drawings, and their repeated descriptions are omitted.

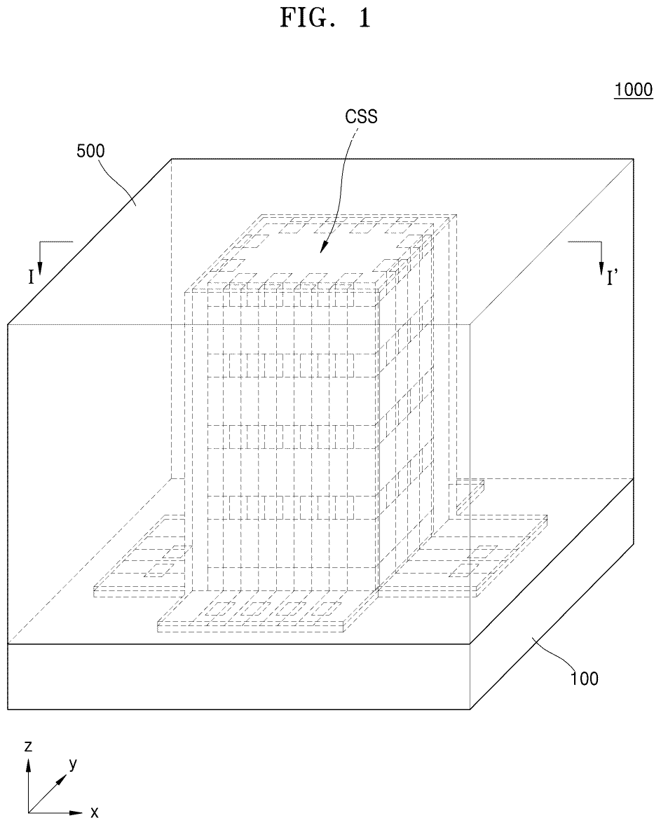

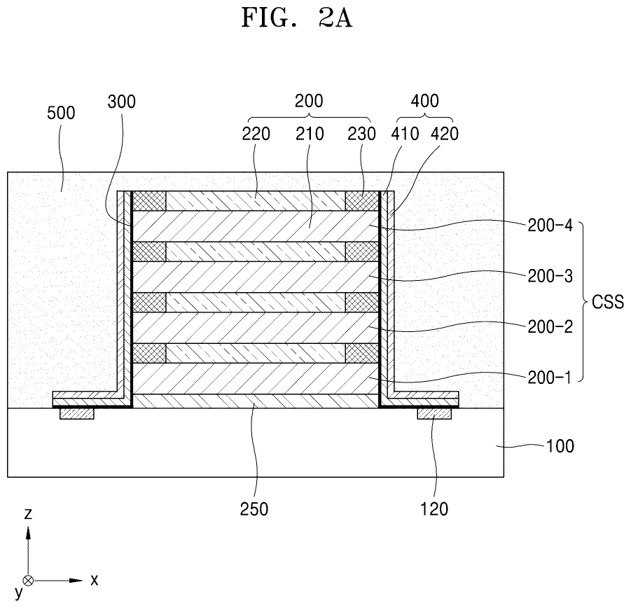

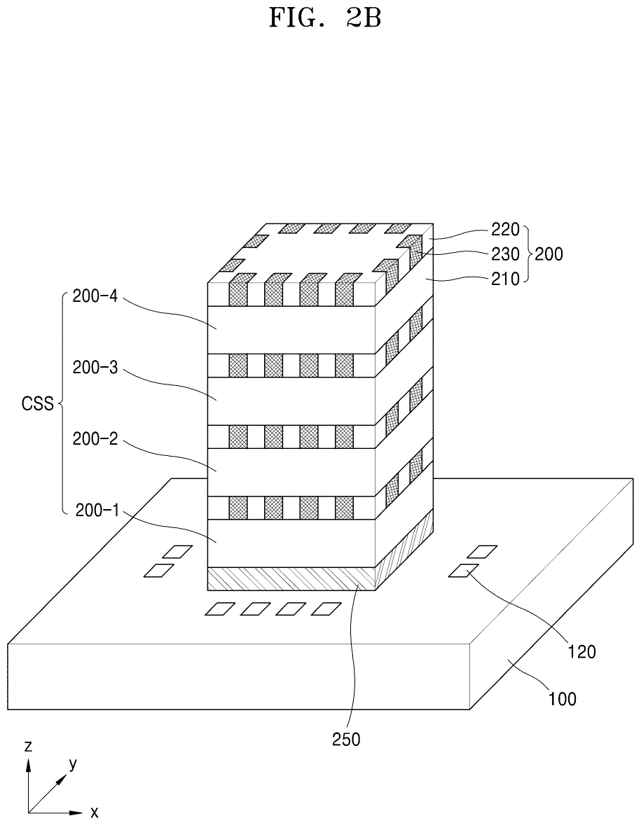

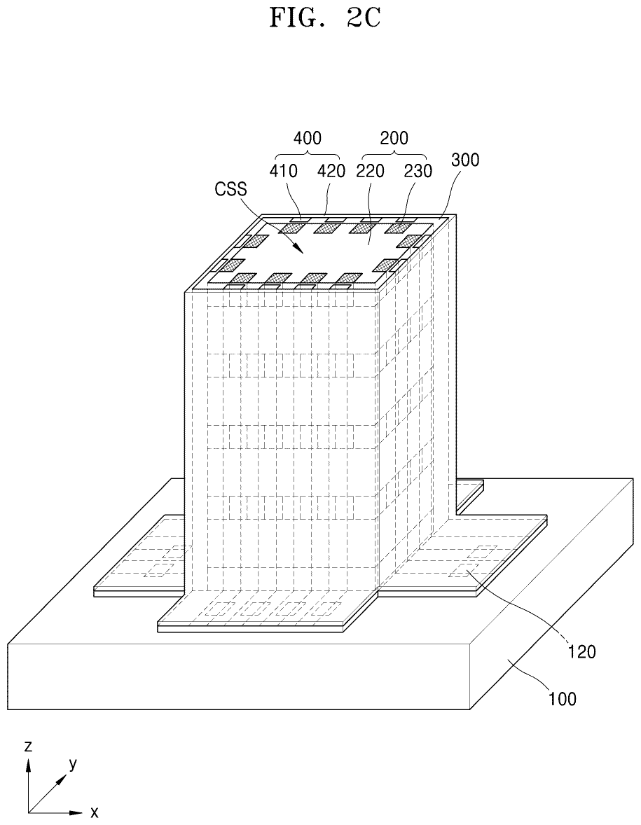

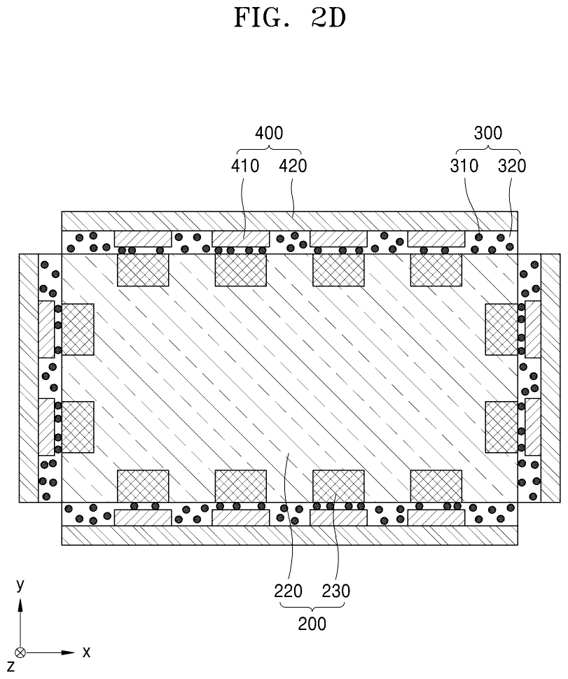

FIG. 1 is a perspective view of a semiconductor package according to some implementations, and FIGS. 2A to 2D are a cross-sectional view, perspective views, and a plan view of the semiconductor package of FIG. 1, respectively. FIG. 2A is a cross-sectional view taken along line I-I′ of the semiconductor package of FIG. 1. FIG. 2B illustrates the semiconductor package in which an anisotropic conductive film, a conductive pattern film, and a sealant are removed, for purposes of illustration. FIG. 2C illustrates the semiconductor package in which a sealant is removed from the semiconductor package, for purposes of illustration. FIG. 2D is a plan view illustrating an upper surface of a chip stack structure portion in the semiconductor package of FIG. 1.

Referring to FIGS. 1 to 2D, a semiconductor package 1000 according to some implementations may include a package substrate 100, a chip stack structure CSS, an anisotropic conductive film (ACF) 300, a conductive pattern film 400, and a sealant 500.

The package substrate 100 may be disposed under the chip stack structure CSS and may support the chip stack structure CSS. The package substrate 100 may include a substrate body, a multi wiring layer, and a solder resist (SR) layer.

The substrate body may include, for example, resin and glass fiber such as frame retardant 4 (FR-4). However, a material of the substrate body is not limited thereto. For example, the substrate body may include bismaleimide triazine (BT) resin, poly carbonate (PC) resin, build-up films such as Ajinomoto build-up film (ABF), or laminate resin.

The multi wiring layer may be disposed in the substrate body. The multi wiring layer may include several or tens of wiring layers. The number of layers of the multi wiring layer is not limited to the numerical range described above. Wirings of the other layers may be connected to one another through a via. The wirings and the via may include metal, for example, copper (Cu). However, materials of the wirings and the via are not limited to Cu. The SR layer may be a layer that protects the substrate body and the multi wiring layer from external physical or chemical damage. The SR layer may be disposed on an upper surface and a lower surface of the substrate body.

In the semiconductor package 1000, the package substrate 100 may be, for example, a printed circuit board (PCB). However, the package substrate 100 is not limited to a PCB. For example, the package substrate 100 may include a ceramic substrate, a glass substrate, an interposer substrate, or a redistribution substrate.

The chip stack structure CSS, as shown in FIGS. 2A and 2B, may include a plurality of semiconductor chips 200 that are stacked on the package substrate 100 in a vertical direction. The semiconductor chips 200 may be the same kind of semiconductor chips. For example, the semiconductor chips 200 may include a volatile memory device, such as dynamic random access memory (RAM) (DRAM) and static RAM (SRAM), or a non-volatile memory device such as flash memory.

The semiconductor chip 200 may include a body layer 210, an active layer 220, and a chip pad 230. The body layer 210 may form a body of the semiconductor chip 200 and may include silicon (Si). However, a material of the body layer 210 is not limited to Si.

The active layer 220 may include an integrated circuit layer and a wiring layer. The integrated circuit layer may be formed by using an impurity region of an upper portion of the body layer 210. For example, the integrated circuit layer may include transistors each including a gate electrode and an impurity region such as a source/drain region. However, elements included in the integrated circuit layer are not limited to transistors. The wiring layer may be disposed on the integrated circuit layer and may include multi-wirings. The multi-wirings may be electrically connected to the integrated circuit layer through a contact. Also, in the wiring layer, wirings of different layers may be connected to each other through a vertical via.

Furthermore, an upper surface of the active layer 220 may correspond to an active surface, and a lower surface of the body layer 210 opposite to the active surface may correspond to an inactive surface. A passivation layer such as an oxide film, a nitride film, or an oxynitride film for protecting the semiconductor chip 200 may be disposed on the upper surface of the active layer 220.

The chip pad 230 may be exposed at a side surface of the semiconductor chip 200. For example, the chip pad 230 may be disposed on the active layer 220 of the semiconductor chip 200. Also, as shown in FIGS. 2A and 2C, the chip pad 230 may be disposed to be exposed at a side surface of the active layer 220. In the semiconductor package 1000, the chip pad 230 may be disposed to be exposed at all of four side surfaces of the active layer 220. As described above, the passivation layer may be disposed on the upper surface of the active layer 220, and thus, the chip pad 230 may not be exposed at the upper surface of the active layer 220. However, according to some implementations, the chip pad 230 may be exposed in a structure passing through the passivation layer, on the upper surface of the active layer 220.

The chip pad 230 may be formed to have a thickness that corresponds to a partial thickness of an upper portion of the active layer 220. In FIG. 2A, the chip pad 230 is illustrated with a thickness corresponding to the total thickness of the active layer 220, so as to illustrate a structure in which the chip pad 230 is exposed at the side surface of the active layer 220. In some implementations, the chip pad 230 may be formed on the side surface of the active layer 220 to have a thickness corresponding to the total thickness of the active layer 220, so as to enlarge a contact area with a conductive pattern 410 of the conductive pattern film 400.

In the semiconductor package 1000, the chip stack structure CSS may include four semiconductor chips 200. For example, the chip stack structure CSS may include first to fourth semiconductor chips 200-1 to 200-4. However, the number of semiconductor chips 200 included in the chip stack structure CSS is not limited to four. For example, the chip stack structure CSS may include two, three, or five or more semiconductor chips 200.

In the chip stack structure CSS, the first semiconductor chip 200-1 that is lowermost may be bonded to the package substrate 100 through an adhesive layer 250. The adhesive layer 250 may be, for example, a die attach film (DAF). However, the adhesive layer 250 is not limited to a DAF. The second semiconductor chip 200-2 may be bonded to the first semiconductor chip 200-1 through oxide bonding. Also, the third semiconductor chip 200-3 may be bonded to the second semiconductor chip 200-2 through oxide bonding, and the fourth semiconductor chip 200-4 may be bonded to the third semiconductor chip 200-3 through oxide bonding.

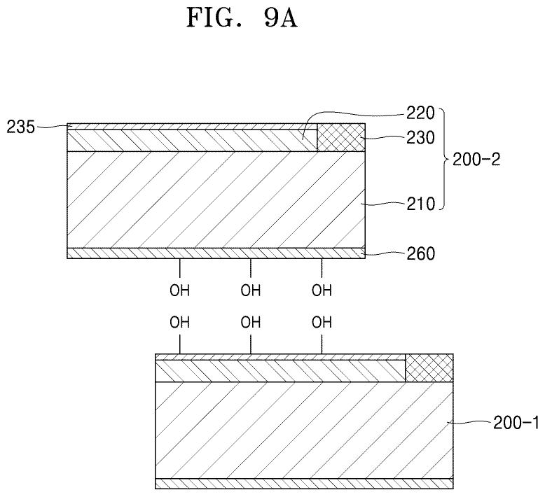

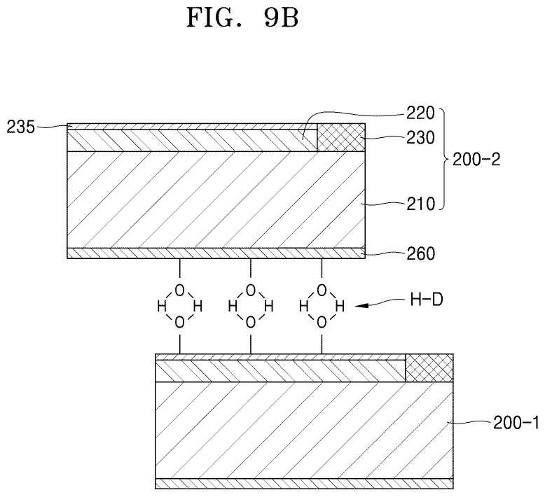

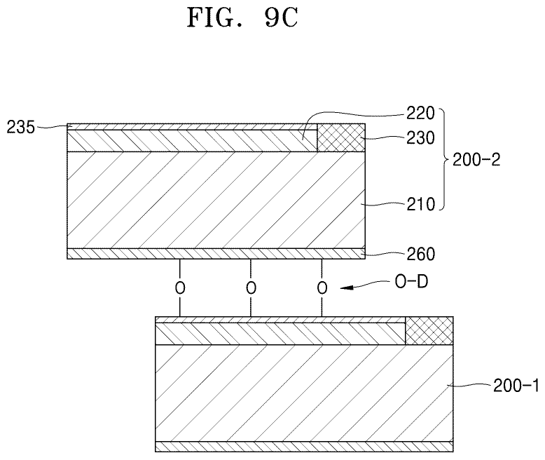

Oxide bonding may be interface bonding between a lower semiconductor chip (for example, a passivation layer of an upper surface of the first semiconductor chip 200-1) and an upper semiconductor chip (for example, an oxide film of a lower surface of the second semiconductor chip 200-2). For example, the passivation layer may be a SiCN layer or a SiN layer and the oxide film may be a SiO₂ layer. However, materials of the passivation layer and the oxide film are not limited to the materials described above. Oxide bonding between the semiconductor chips 200 is described in more detail with respect to FIGS. 9A to 9C.

In the semiconductor package 1000, the semiconductor chips 200 of the chip stack structure CSS may be aligned and stacked with one another in a vertical direction (e.g., a z direction) of the package substrate 100. Here, the alignment may denote the alignment of side surfaces of the semiconductor chips 200 with one another. For example, the side surfaces of the semiconductor chips 200 may be aligned with one another in the vertical direction. Also, in a case where the side surfaces of the semiconductor chips 200 are very precisely aligned with one another in the vertical direction, the side surfaces of the semiconductor chips 200 may form substantially the same common flat surface.

The ACF 300 may cover four side surfaces of the chip stack structure CSS and a partial upper surface of the package substrate 100. For example, the ACF 300 may extend in the z direction at each of the four side surfaces of the chip stack structure CSS. Also, the ACF 300 may be bent or curved by about 90 degrees at a bonding portion between the chip stack structure CSS and the package substrate 100 and may extend in an x direction and/or a y direction, on the upper surface of the package substrate 100. For example, the ACF 300 may extend in the z direction and may be bent by about 90 degrees at the bonding portion, at both side surfaces of the chip stack structure CSS in the x direction, and moreover, may extend in the x direction on the upper surface of the package substrate 100. Also, the ACF 300 may extend in the z direction and may be bent by about 90 degrees at the bonding portion, at both side surfaces of the chip stack structure CSS in the y direction, and moreover, may extend in the y direction on the upper surface of the package substrate 100. Furthermore, as shown in FIG. 2A, the ACF 300 may cover a substrate pad 120 of the package substrate 100. For example, the ACF 300 may extend on the upper surface of the package substrate 100 up to a portion beyond the substrate pad 120 of the package substrate 100 from the bonding portion. For reference, the ACF 300 may be an ACF which allows electricity to flow in only one direction and may include fine conductive particles 310 and adhesive resin 320, as shown in FIG. 2D. For example, the ACF 300 may be an ACF which is formed in a film state by combining the conductive particles 310 with the adhesive resin 320 having adhesive properties and insulating properties.

The conductive pattern film 400 may cover the ACF 300. Similar to the ACF 300, the conductive pattern film 400 may cover the four side surfaces of the chip stack structure CSS and a partial upper surface of the package substrate 100. For example, the conductive pattern film 400 may extend in the z direction on the ACF 300 of each of the four side surfaces of the chip stack structure CSS. Also, the conductive pattern film 400 may be bent by about 90 degrees at the bonding portion between the chip stack structure CSS and the package substrate 100 and may extend in the x direction and/or the y direction, on the ACF 300 on the upper surface of the package substrate 100. For example, the conductive pattern film 400 may extend in the z direction and may be bent by about 90 degrees at the bonding portion, on the ACF 300 on the both side surfaces of the chip stack structure CSS in the x direction, and moreover, may extend in the x direction on the ACF 300 on the upper surface of the package substrate 100. Also, the conductive pattern film 400 may extend in the z direction and may be bent by about 90 degrees at the bonding portion, on the ACF 300 on the both side surfaces of the chip stack structure CSS in the y direction, and moreover, may extend in the y direction on the ACF 300 on the upper surface of the package substrate 100. Furthermore, as shown in FIG. 2A, similar to the ACF 300, the conductive pattern film 400 may extend on the ACF 300 on the upper surface of the package substrate 100 up to a portion beyond the substrate pad 120 of the package substrate 100 from the bonding portion.

The conductive pattern film 400 may include a conductive pattern 410 and a polymer film 420. The conductive pattern 410 may include a conductive material. For example, the conductive pattern 410 may include metal such as Cu, aluminum (Al), nickel (Ni), tin (Sn), silver (Ag), or gold (Au). In some implementations, the conductive pattern 410 may include polysilicon, a conductive oxide film, or a conductive nitride film. In the semiconductor package 1000, the conductive pattern 410 may include, for example, Cu. However, a material of the conductive pattern 410 is not limited to the materials described above. The polymer film 420 may include, for example, polyimide (PI). However, a material of the polymer film 420 is not limited to PI.

The conductive pattern 410 may be disposed on the polymer film 420. For example, the conductive pattern 410 may extend on the polymer film 420 in a direction in which the polymer film 420 extends (e.g., the z direction), and moreover, a plurality of conductive patterns 410 may be arranged spaced apart from one another on the polymer film 420 in a direction perpendicular to an extension direction (e.g., the x direction or the y direction).

To describe the four side surfaces of the chip stack structure CSS in more detail, the conductive pattern 410 may extend in the z direction on the ACF 300 on each of the four side surfaces of the chip stack structure CSS. Also, the conductive pattern 410 may be bent by about 90 degrees at the bonding portion between the chip stack structure CSS and the package substrate 100 and may extend in the x direction or the y direction, on the ACF 300 on the upper surface of the package substrate 100. In a case (e.g., for a side surface) where the polymer film 420 extends in the x direction on the upper surface of the package substrate 100, the conductive patterns 410 on the polymer film 420 may be arranged spaced apart from one another in the y direction on the corresponding side surface of the chip stack structure CSS. Also, in a case where the polymer film 420 extends in the y direction on the upper surface of the package substrate 100, the conductive patterns 410 on the polymer film 420 may be arranged spaced apart from one another in the x direction on the corresponding side surface of the chip stack structure CSS.

The conductive pattern 410 may connect, with one another, corresponding chip pads 230 of the semiconductor chips 200 of the chip stack structure CSS. Also, the conductive pattern 410 may connect the chip pads 230 of the semiconductor chips 200 to a corresponding substrate pad 120 of the package substrate 100. As a result, the semiconductor chips 200 of the chip stack structure CSS may be electrically connected to the package substrate 100 through the conductive pattern 410. As illustrated in FIG. 2D, in a plan view (top view), a separation interval between the conductive patterns 410 may be substantially the same as a separation interval between the chip pads 230 of the semiconductor chip 200. For example, a separation interval between the conductive patterns 410 in the y direction may be substantially the same as a separation interval between the chip pads 230 of the semiconductor chip 200 in the y direction, at both side surfaces of the semiconductor chip 200 in the x direction. Also, a separation interval between the conductive patterns 410 in the x direction may be substantially the same as a separation interval between the chip pads 230 of the semiconductor chip 200 in the x direction, at both side surfaces of the semiconductor chip 200 in the y direction.

In some implementations, at least some of the conductive patterns 410 may extend in the x direction, the y direction, an x-z direction, or a y-z direction as well as the z direction, at the side surfaces of the semiconductor chips 200 of the chip stack structure CSS. In a case where the conductive patterns 410 extend in the x direction, the y direction, or a diagonal (x-z or y-z) direction, the conductive patterns 410 may overlap each other, and in this case, an insulation layer may be disposed between the overlapping conductive patterns 410. Also, as seen in FIG. 2D, the conductive pattern 410 may be electrically connected to corresponding chip pads 230 of the semiconductor chips 200 of the chip stack structure CSS through the conductive particles 310 of the ACF 300. For example, a conductive path may be formed between the conductive pattern 410 and corresponding chip pads 230 by using the conductive particles 310. In some implementations, the conductive pattern 410 may be directly connected to the chip pads 230.

The sealant 500 may seal the chip stack structure CSS on the package substrate 100. The sealant 500 may include an insulating material (for example, thermo-curable resin such as epoxy resin or thermo-plastic resin such as polyimide). The sealant 500 may include resin (for example, ABR, FR-4, or BT resin) where a stiffener such as an inorganic filler is added to thermo-curable resin or thermo-plastic resin. Also, a photosensitive material such as a photo imageable encapsulant (PIE) or a molding material such as an epoxy molding compound (EMC) may be used in the sealant 500. In the semiconductor package 1000, the sealant 500 may include, for example, an EMC. However, a material of the sealant 500 is not limited to the materials described above.

In the semiconductor package 1000, in some implementations, the first semiconductor chip 200-1 that is lowermost may be bonded to the package substrate 100 by using the adhesive layer 250 such as a DAF, and the upper semiconductor chip 200 may be interface-bonded to the lower semiconductor chip 200 through oxide bonding. Accordingly, the total height of a package may decrease by the thickness of the adhesive layer 250 (e.g., by the thickness of the adhesive layer 250 that would otherwise be used for bonding), and the material cost of the adhesive layer 250 such as a DAF may be reduced. Moreover, in the semiconductor package 1000, in some implementations, electrical connections between the semiconductor chips 200 and the package substrate 100 may be implemented by using the conductive pattern film 400 and the chip pads 230 exposed at a side surface, and thus, the semiconductor chips 200 may be stacked on the package substrate 100 in a vertical form instead of a staircase form. As a result, a planar area of a package may be considerably reduced compared to a package structure stacked in a staircase form. Furthermore, in the semiconductor package 1000, in some implementations, the semiconductor chips 200 may be electrically connected to the package substrate 100 through the conductive pattern film 400 instead of a wire, and thus, a height of a package may additionally decrease by a height of a wire loop. For reference, in the semiconductor package 1000, in some implementations, the ACF 300 on the four side surfaces of the chip stack structure CSS may complement a horizontal bonding force between the semiconductor chips 200 capable of being weakened by the removal of the adhesive layer 250, based on a vertical bonding force.

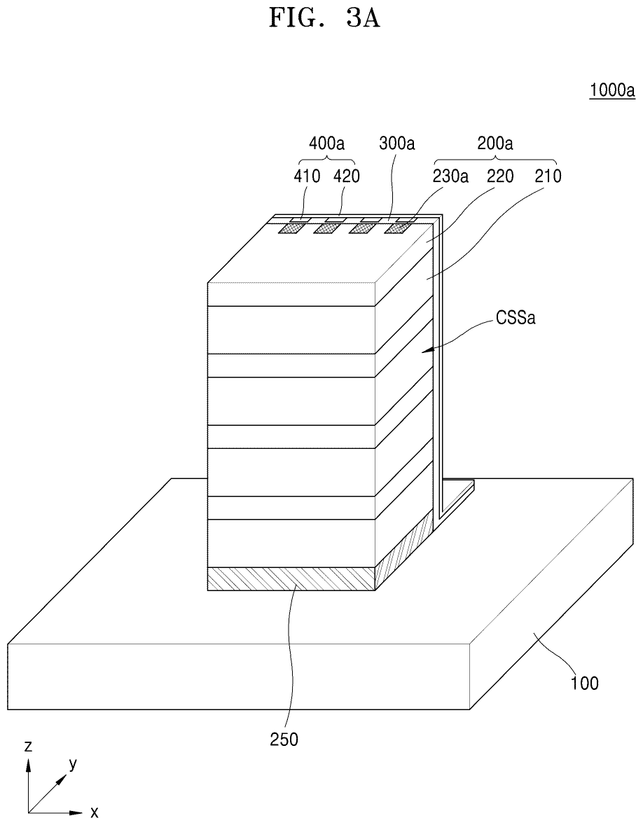

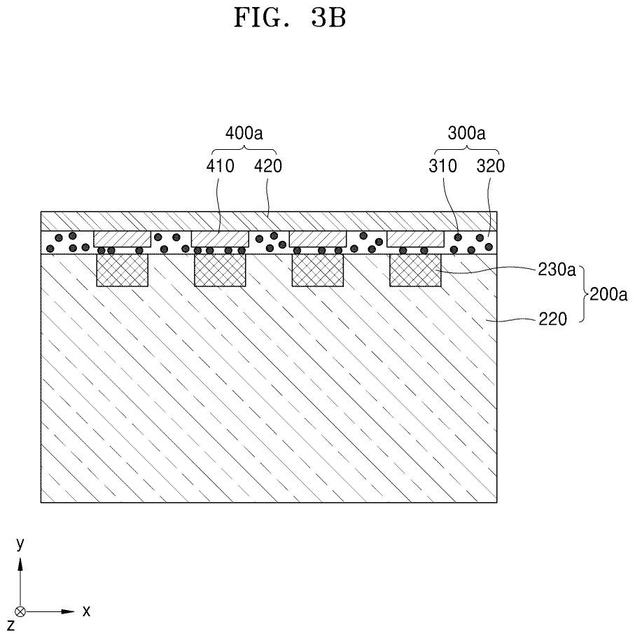

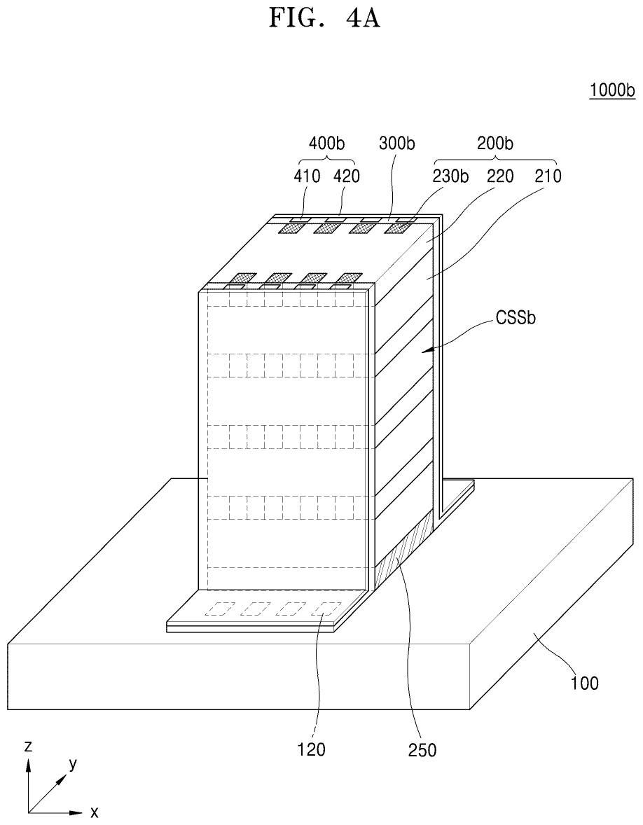

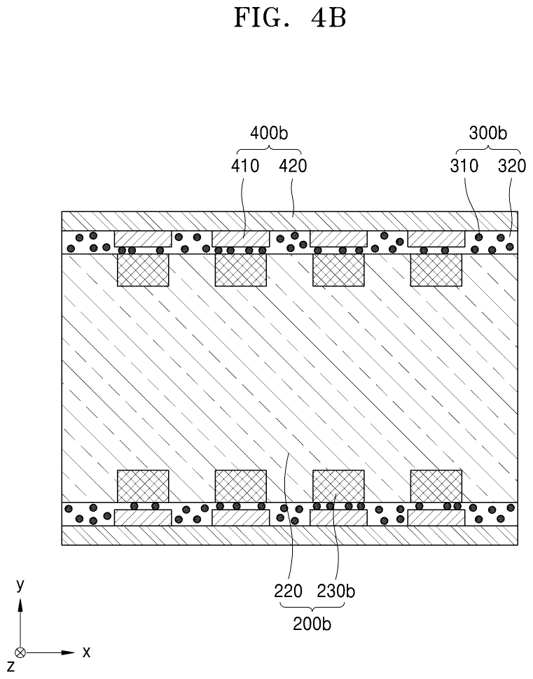

FIGS. 3A and 4A are perspective views of examples of semiconductor packages in which a sealant is omitted for purposes of illustration, and FIGS. 3B and 4B are plan views illustrating upper surfaces of a chip stack structure portion in the semiconductor packages of FIGS. 3A and 4A. Descriptions which are the same as or similar to the descriptions of FIGS. 1 to 2D are briefly given or are omitted, and can equally apply to the packages of FIGS. 3A to 4B except where noted otherwise or suggested otherwise by context.

Referring to FIGS. 3A and 3B, a semiconductor package 1000a according to some implementations may differ from the semiconductor package 1000 of FIG. 1. The semiconductor package 1000a includes a semiconductor chip 200a and a structure of a chip stack structure CSSa based thereon, an ACF 300a, and a structure of a conductive pattern film 400a. In the semiconductor package 1000a according to some implementations, the semiconductor chip 200a may include a body layer 210, an active layer 220, and a chip pad 230a. Also, in the semiconductor chip 200a, the chip pad 230a may be disposed to be exposed at one of four side surfaces of the semiconductor chip 200a (for example, one of two side surfaces extending in an x direction). Also, four semiconductor chips 200a configuring the chip stack structure CSSa may have substantially the same structure. For example, in the chip stack structure CSSa, the chip pads 230a may be disposed to be exposed at the same one side surface in each of the four semiconductor chips 200a.

Furthermore, as the chip pads 230a are exposed at only one side surface of a corresponding semiconductor chip 200a, the ACF 300a and the conductive pattern film 400a may extend in a z direction at the one side surface of the chip stack structure CSSa and may extend on a partial upper surface of the package substrate 100 corresponding to the one side surface of the chip stack structure CSSa. Also, substrate pads (see 120 of FIG. 2A) may be disposed on the upper surface of the package substrate 100, and the substrate pads 120 may be covered by the ACF 300a and the conductive pattern film 400a each extending on the upper surface of the package substrate 100.

For example, in the semiconductor package 1000a, the chip pads 230a may be disposed along the x direction at an upper side surface of the semiconductor chip 200a in the y direction. Also, the ACF 300a and the conductive pattern film 400a may be disposed on an upper side surface of the chip stack structure CSSa in the y direction and extend in the z direction, and may be bent by about 90 degrees at the bonding portion to extend in the y direction on the upper surface of the package substrate 100. The ACF 300a and the conductive pattern film 400a each extending in the y direction on the upper surface of the package substrate 100 may cover the substrate pad 120 on the upper surface of the package substrate 100.

Referring to FIGS. 4A and 4B, a semiconductor package 1000b according to some implementations may differ from the semiconductor package 1000 of FIG. 1. The semiconductor package 1000b includes a semiconductor chip 200b and a structure of a chip stack structure CSSb based thereon, an ACF 300b, and a structure of a conductive pattern film 400b. In the semiconductor package 1000b according to some implementations, the semiconductor chip 200b may include a body layer 210, an active layer 220, and a chip pad 230b. Also, in the semiconductor chip 200b, the chip pad 230b may be disposed to be exposed at two side surfaces, which are opposite to each other, of four side surfaces of the semiconductor chip 200b (for example, two side surfaces extending in an x direction). Also, four semiconductor chips 200b configuring the chip stack structure CSSb may have substantially the same structure. For example, in the chip stack structure CSSb, the chip pads 230b may be disposed to be exposed at two side surfaces opposite to each other in each of the four semiconductor chips 200b.

As the chip pads 230b are exposed at two side surfaces, which are opposite to each other, of a corresponding semiconductor chip 200b, the ACF 300b and the conductive pattern film 400b may extend in a z direction on two side surfaces, which are opposite to each other, of the chip stack structure CSSb and may extend on a partial upper surface of the package substrate 100 corresponding to the side surfaces thereof. Substrate pads 120 may be disposed on the upper surface of the package substrate 100, and the substrate pads 120 may be covered by the ACF 300b and the conductive pattern film 400b each extending on the upper surface of the package substrate 100.

For example, in the semiconductor package 1000b according to some implementations, the chip pads 230b may be disposed along the x direction at both side surfaces of the semiconductor chip 200b in the y direction. Also, the ACF 300b and the conductive pattern film 400b may be disposed at both side surfaces of the chip stack structure CSSb in the y direction and extend in the z direction, and may be bent by about 90 degrees at the bonding portion to extend in the y direction on the upper surface of the package substrate 100. The ACF 300b and the conductive pattern film 400b each extending in the y direction on the upper surface of the package substrate 100 may cover the substrate pad 120 on the upper surface of the package substrate 100.

Above, structures have been described where the chip pad 230a is exposed at one side surface of the semiconductor chip 200a and the chip pad 230b is exposed at two opposite side surfaces of the semiconductor chip 200b, and, correspondingly, the ACF 300a and the conductive pattern film 400a cover one of side surface the chip stack structure CSSa and extend onto the package substrate 100, and the ACF 300b and the conductive pattern film 400b cover two side surfaces of the chip stack structure CSSb and extend onto the package substrate 100. However, a structure of semiconductor packages within the scope of this disclosure is not limited thereto. For example, chip pads may be disposed to be exposed at three side surfaces of a semiconductor chip or exposed at two adjacent side surfaces of the semiconductor chip. Also, an ACF and a conductive pattern film may cover any side surfaces of a chip stack structure at which chip pads are exposed and may extend on the upper surface of the package substrate 100.

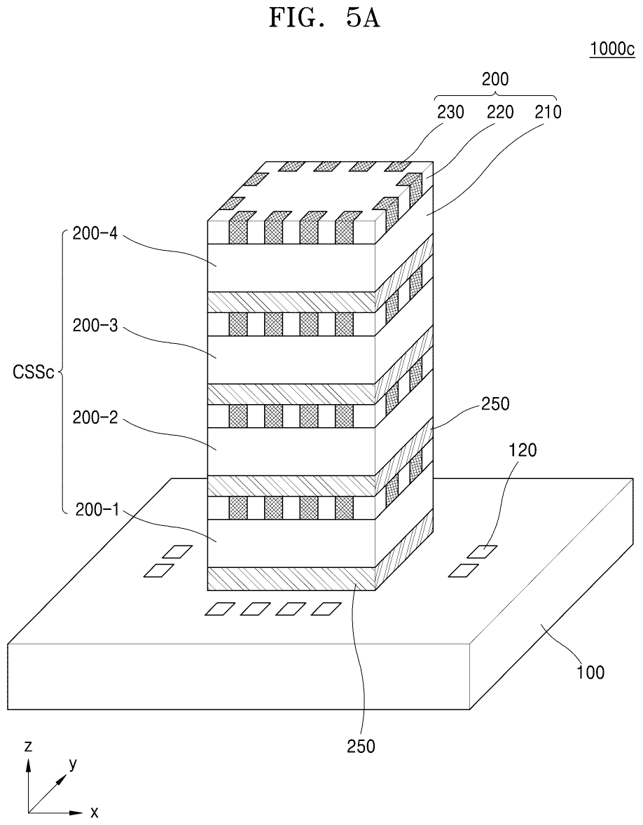

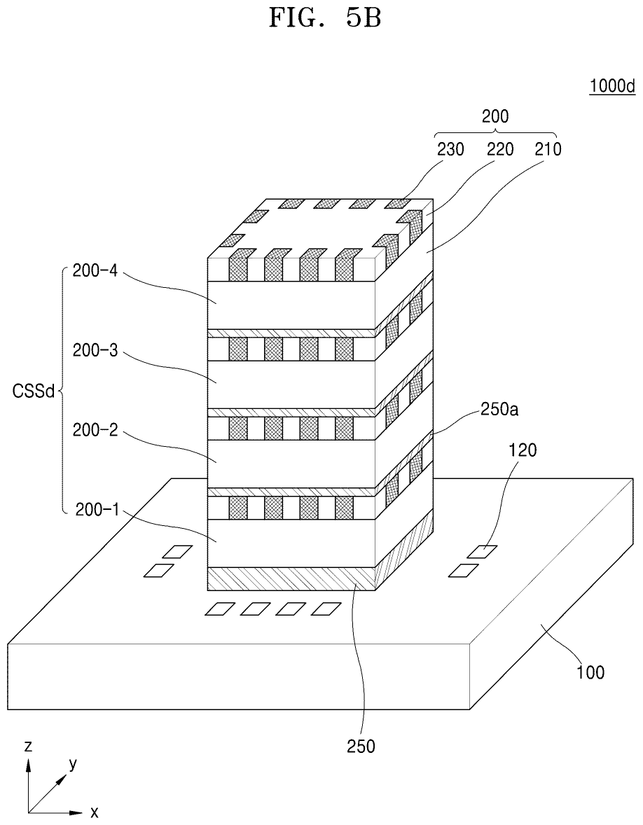

FIGS. 5A and 5B are perspective views of semiconductor packages according to some implementations. For purposes of illustration, FIGS. 5A and 5B and illustrate only a package substrate and a chip stack structure, and omit a sealant, an ACF, and a conductive pattern film that can be included in the semiconductor packages. Descriptions which are the same as or similar to the descriptions of FIGS. 1 to 4B are briefly given or are omitted, and can equally apply to the packages of FIGS. 5A to 5B except where noted otherwise or suggested otherwise by context

Referring to FIG. 5A, a semiconductor package 1000c according to some implementations may differ from the semiconductor package 1000 of FIG. 1. In the semiconductor package 1000c, a semiconductor chip 200 may be substantially the same as the semiconductor chip 200 of the semiconductor package 1000 of FIG. 1. Also, an ACF and a conductive pattern film may be substantially the same as the ACF 300 and the conductive pattern film 400 of the semiconductor package 1000 of FIG. 1.

In the semiconductor package 1000c according to some implementations, a stack structure of semiconductor chips 200 of the chip stack structure CSSc may differ from the stack structure of the semiconductor chips 200 of the chip stack structure CSS of the semiconductor package 1000 of FIG. 1. For example, in the semiconductor package 1000c, the semiconductor chips 200 of the chip stack structure CSSc may be bonded to a package substrate 100 or a lower semiconductor chip 200 by using an adhesive layer 250 such as a DAF and may be stacked. For example, a bond between adjacent semiconductor chips 200 by oxide bonding may not be implemented. For example, a first semiconductor chip 200-1 may be bonded to the package substrate 100 by the adhesive layer 250, and a second semiconductor chip 200-2 may be bonded to the first semiconductor chip 200-1 by the adhesive layer 250. Also, a third semiconductor chip 200-3 may be bonded to the second semiconductor chip 200-2 by the adhesive layer 250, and a fourth semiconductor chip 200-4 may be bonded to the third semiconductor chip 200-3 by the adhesive layer 250.

Referring to FIG. 5B, a semiconductor package 1000d according to some implementations may be similar to the semiconductor package 1000c of FIG. 5A in a structure of a chip stack structure CSSd. For example, in the semiconductor package 1000d, a semiconductor chip 200 may be substantially the same as the semiconductor chip 200 of the semiconductor package 1000c of FIG. 5A. Also, an ACF and a conductive pattern film may be substantially the same as the ACF and the conductive pattern film of the semiconductor package 1000c of FIG. 5A.

However, in the semiconductor package 1000d according to some implementations, a stack structure of semiconductor chips 200 of the chip stack structure CSSd may differ from the stack structure of the semiconductor chips 200 of the chip stack structure CSSc of the semiconductor package 1000c of FIG. 5A. For example, in the semiconductor package 1000d, second to fourth semiconductor chips 200-2 to 200-4 of the semiconductor chips 200 of the chip stack structure CSSd may be bonded to a lower semiconductor chip 200 by using a polymer adhesive layer 250a and may be stacked. For example, the second semiconductor chip 200-2 may be bonded to the first semiconductor chip 200-1 by the polymer adhesive layer 250a. Also, the third semiconductor chip 200-3 may be bonded to the second semiconductor chip 200-2 by the polymer adhesive layer 250a, and the fourth semiconductor chip 200-4 may be bonded to the third semiconductor chip 200-3 by the polymer adhesive layer 250a.

Furthermore, a bond by oxide bonding based on the polymer adhesive layer 250a may be implemented between adjacent semiconductor chips 200. For oxide bonding based on the polymer adhesive layer 250a, when surface processing is performed on a bond interface through plasma processing and de-ionized (DI) water cleaning, a bond based on a hydrogen bond may be implemented in a C-stage at room temperature. Subsequently, oxide bonding based on a covalent bond may be completed through high-temperature annealing. For example, the polymer adhesive layer 250a may be thinly coated on the semiconductor chip 200 in a liquid state (for example, a thickness of about 1 μm or less) and may then be cured and attached on the semiconductor chip 200. Plasma processing and DI water cleaning may be performed on a cured polymer adhesive layer 250a.

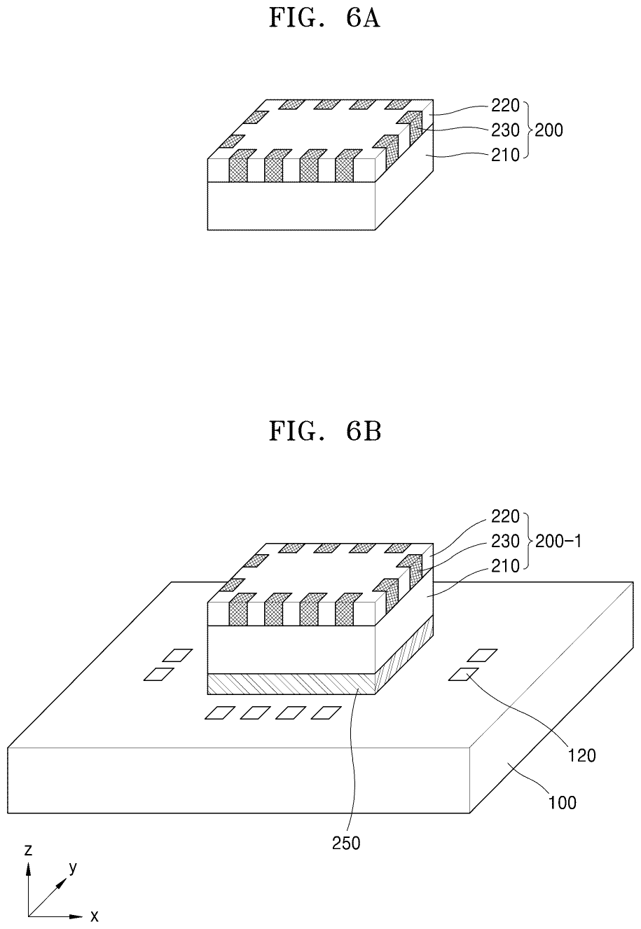

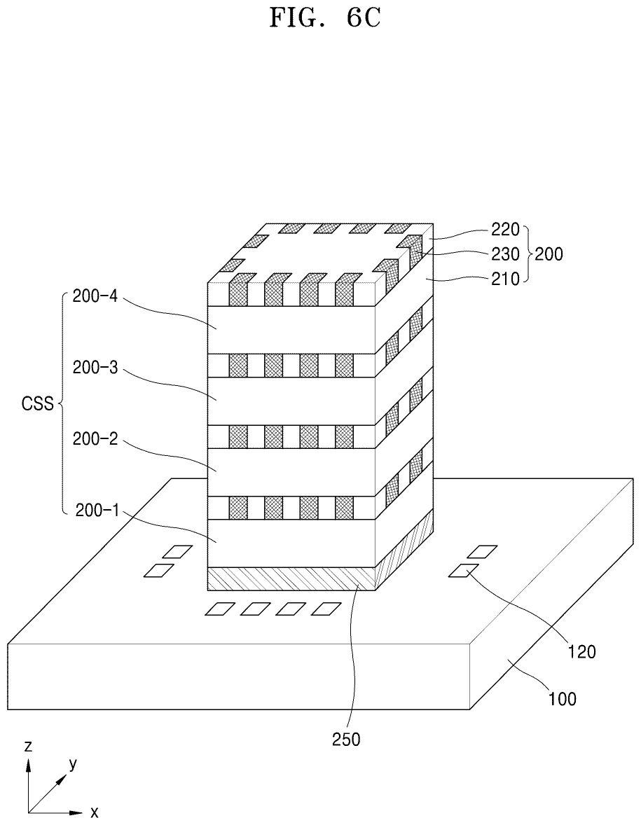

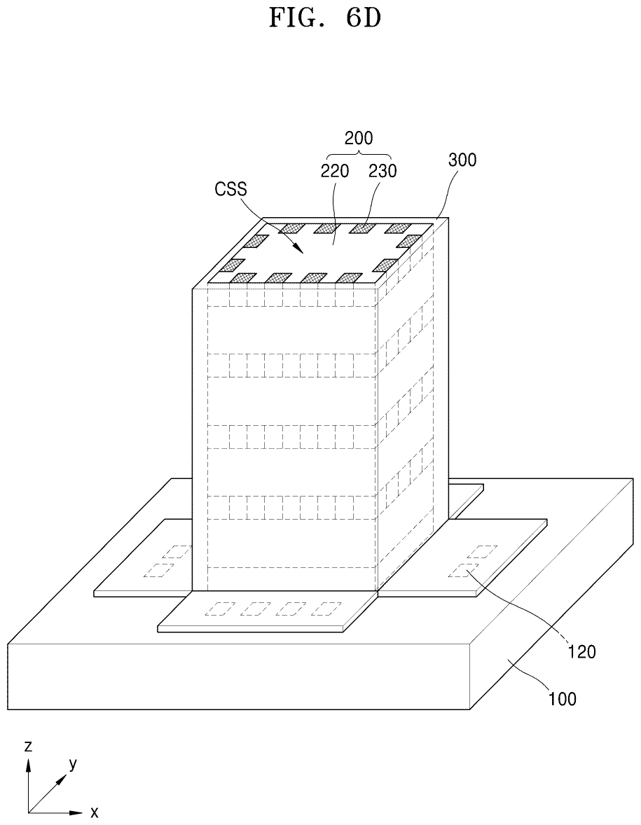

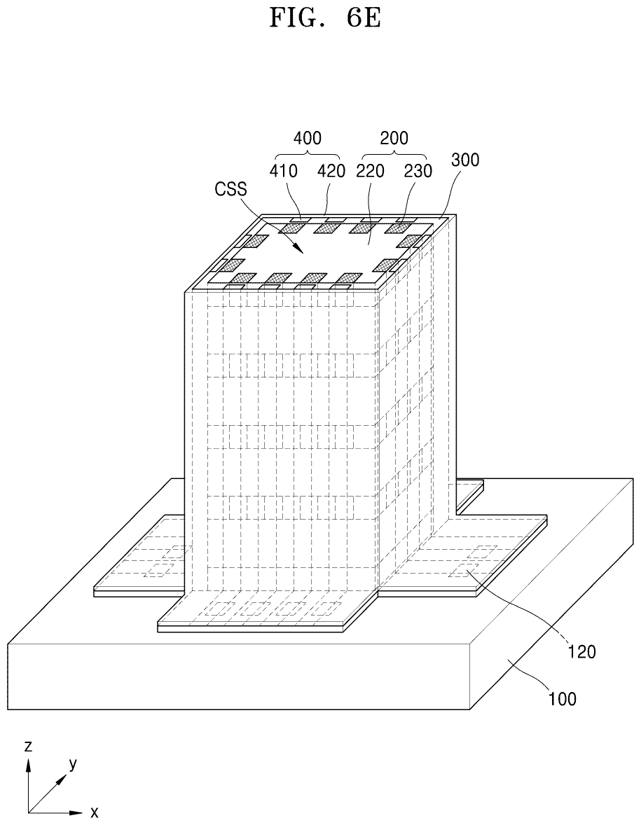

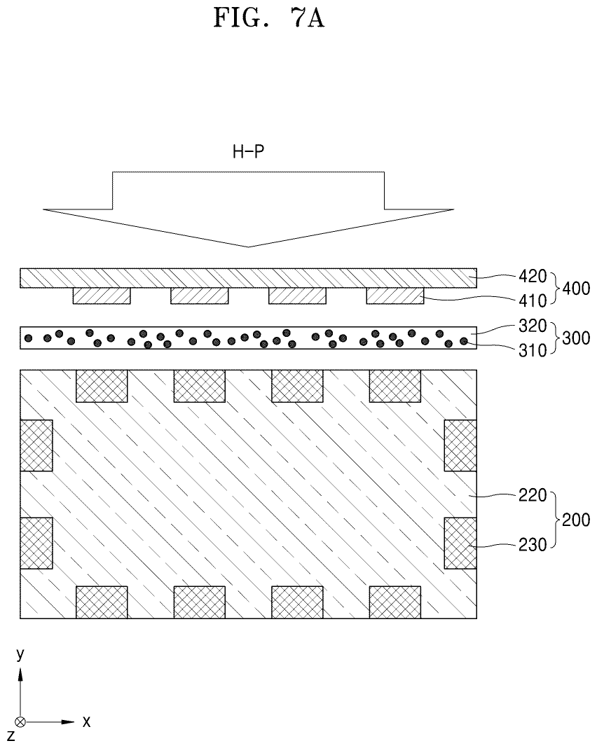

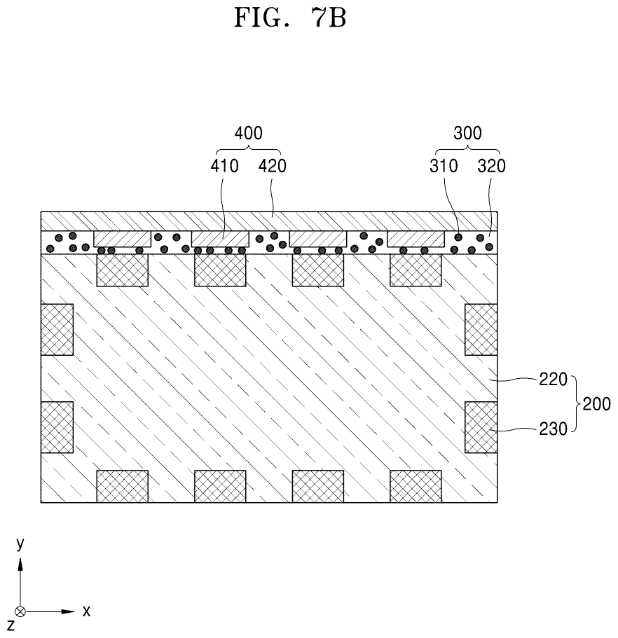

FIGS. 6A to 6E are perspective views illustrating a process of manufacturing a semiconductor package, according to some implementations, and FIGS. 7A and 7B are plan views illustrating in more detail a process of attaching a conductive pattern film, e.g., as shown in FIG. 6E. FIGS. 6A to 6E, 7A, and 7B are described with reference to FIGS. 1 to 2D, and descriptions which are the same as or similar to the descriptions of FIGS. 1 to 5B are briefly given or are omitted. It will be understood that the processes of FIGS. 6A to 6B, 7A, and 7B, or portions thereof, can be applied to form the semiconductor packages of FIGS. 1 to 5B.

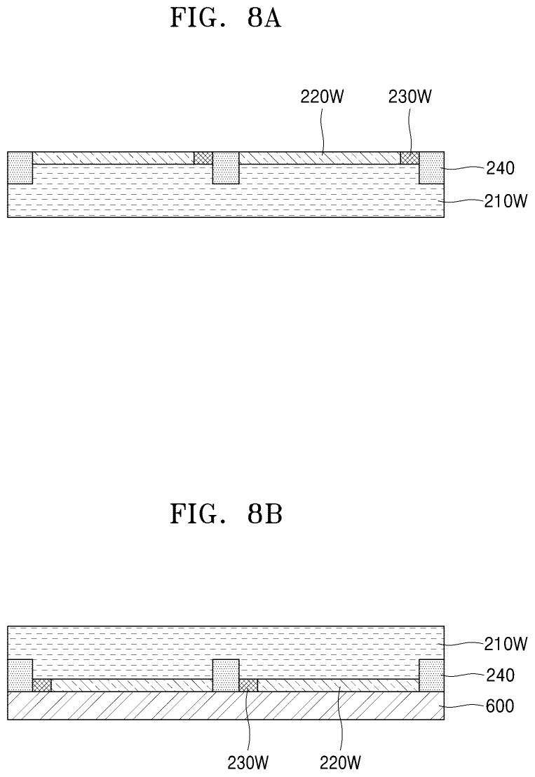

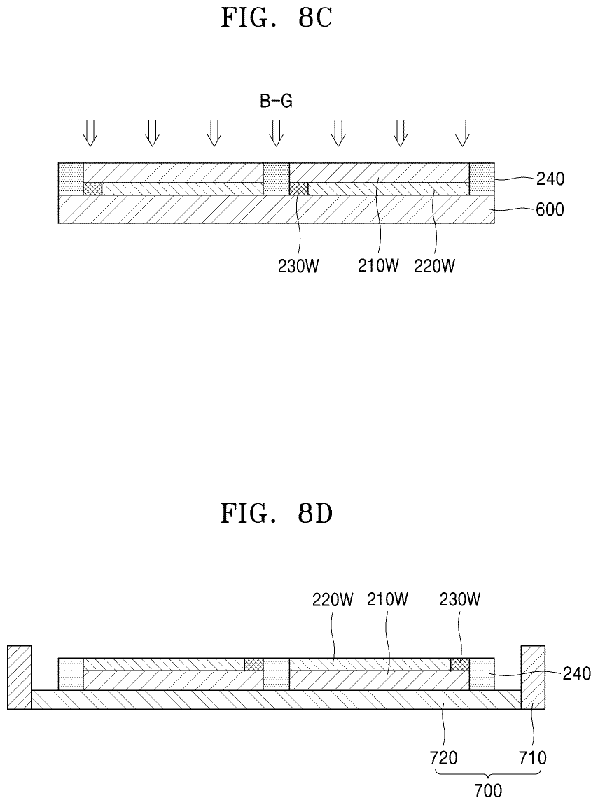

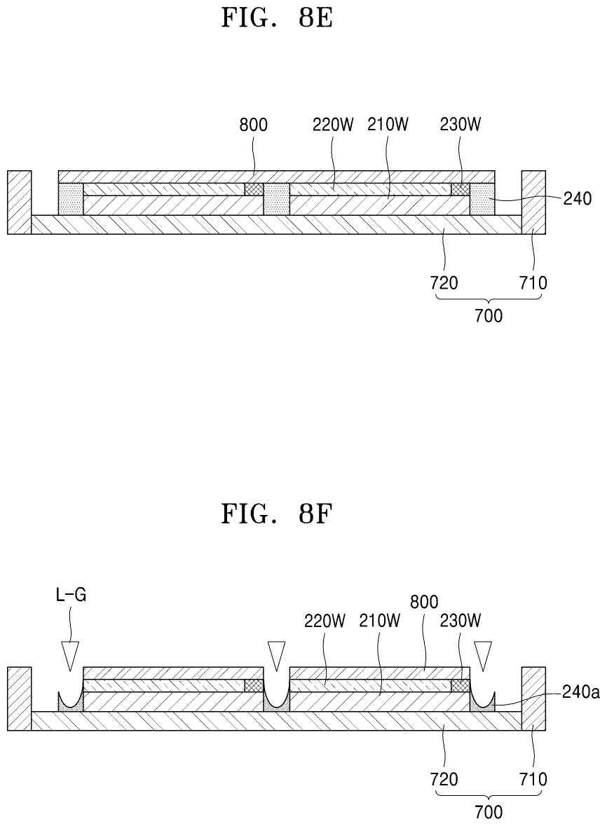

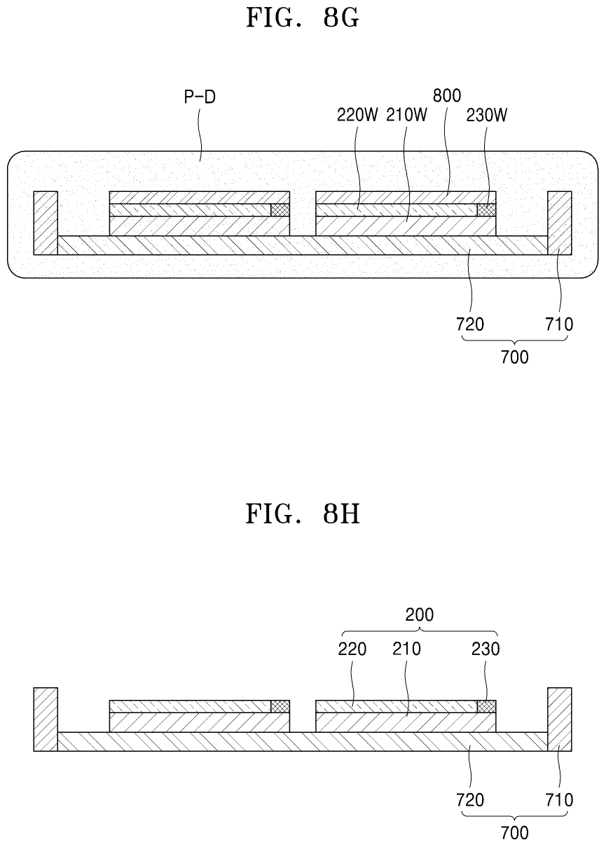

Referring to FIG. 6A, the process may include preparing a plurality of semiconductor chips 200. Each of the semiconductor chips 200 may include a body layer 210, an active layer 220, and a chip pad 230. The chip pads 230 may be exposed at side surfaces of the active layer 220. A description of a structure or a material of the semiconductor chip 200 may be the same as the description of the semiconductor package 1000 of FIG. 1. The semiconductor chips 200 may be manufactured through various semiconductor processes in a Si wafer. A process of preparing or manufacturing the semiconductor chips 200 is described in more detail with reference to FIGS. 8A to 8H.

Referring to FIG. 6B, the semiconductor chips 200 may be prepared, and then, one semiconductor chip 200 may be stacked on a package substrate 100. The semiconductor chip 200 may be bonded to and stacked on a center portion of an upper surface of the package substrate 100 by using an adhesive layer 250 such as a DAF. Hereinafter, a lowermost semiconductor chip 200 stacked on the upper surface of the package substrate 100 may be referred to as a first semiconductor chip 200-1.

The package substrate 100 may include a substrate body, a multi wiring layer, and an SR layer. The package substrate 100 may be, for example, a PCB. Also, as illustrated in FIG. 6B, a substrate pad 120 may be disposed at an outer portion of the upper surface of the package substrate 100. A description of a structure or a material of the package substrate 100 may be the same as the description of the semiconductor package 1000 of FIG. 1.

Referring to FIG. 6C, a first semiconductor chip 200-1 may be stacked, and then, a chip stack structure CSS may be formed by stacking a plurality of semiconductor chips 200 on the first semiconductor chip 200-1. For example, a second semiconductor chip 200-2 may be stacked on the first semiconductor chip 200-1, a third semiconductor chip 200-3 may be stacked on the second semiconductor chip 200-2, and a fourth semiconductor chip 200-4 may be stacked on the third semiconductor chip 200-3. Also, the semiconductor chips 200 may be aligned with one another and stacked in a vertical direction (e.g., a z direction). For example, in the chip stack structure CSS, side surfaces of the semiconductor chips 200 may be aligned with one another in the vertical direction.

Furthermore, in the method of manufacturing a semiconductor package, according to some implementations, the second to fourth semiconductor chips 200-2 to 200-4 may be bonded to a lower semiconductor chip 200 through oxide bonding. For example, the second semiconductor chip 200-2 may be bonded to the first semiconductor chip 200-1 through oxide bonding, the third semiconductor chip 200-3 may be bonded to the second semiconductor chip 200-2 through oxide bonding, and the fourth semiconductor chip 200-4 may be bonded to the third semiconductor chip 200-3 through oxide bonding. Oxide bonding between the semiconductor chips 200 is described in more detail with respect to FIGS. 9A to 9C.

In the method of manufacturing a semiconductor package according to some implementations, a bonding process between the semiconductor chips 200 is not limited to oxide bonding. For example, a bond may be performed between the semiconductor chips 200 by an adhesive layer such as a DAF (e.g., a polymer adhesive layer as described with respect to FIG. 5B). In a case where a bond is performed between the semiconductor chips 200 by the adhesive layer, the semiconductor package 1000d of FIG. 5B may be manufactured as a result of the process.

Referring to FIG. 6D, the chip stack structure CSS may be formed, and then, an ACF 300 may be attached on a partial upper surface of the package substrate 100 and four side surfaces of the chip stack structure CSS. The ACF 300 may include conductive particles 310 and insulating adhesive resin 320. The ACF 300 may extend in the vertical direction (e.g., the z direction) at each of side surfaces of the chip stack structure CSS, may be bent by about 90 degrees at a bonding portion between the chip stack structure CSS and the package substrate 100, and may extend in an x direction or a y direction on the upper surface of the package substrate 100 to cover a corresponding substrate pad 120. For example, the ACF 300 may extend in the z direction and may be bent by about 90 degrees at the bonding portion, at both side surfaces of the chip stack structure CSS in the x direction, and moreover, may extend in the x direction on the upper surface of the package substrate 100. Also, the ACF 300 may extend in the z direction and may be bent by about 90 degrees at the bonding portion, at both side surfaces of the chip stack structure CSS in the y direction, and moreover, may extend in the y direction on the upper surface of the package substrate 100.

Substrate pads 120 may be arranged in the y direction on the upper surface of the package substrate 100 to correspond to both side surfaces of the chip stack structure CSS in the x direction, and the substrate pads 120 may be covered by the ACF 300 extending in the x direction on the upper surface of the package substrate 100. Also, substrate pads 120 may be arranged in the x direction on the upper surface of the package substrate 100 to correspond to both side surfaces of the chip stack structure CSS in the y direction, and the substrate pads 120 may be covered by the ACF 300 extending in the y direction on the upper surface of the package substrate 100.

Referring to FIG. 6E, the ACF 300 may be attached, and then, a conductive pattern film 400 may be attached on the ACF 300. The conductive pattern film 400 may include conductive patterns 410 and a polymer film 420. The conductive patterns 410 may extend in one direction on the polymer film 40 and may be arranged spaced apart from one another in a direction perpendicular to an extension direction. For example, as seen in FIG. 7A, in the conductive pattern film 400 attached on the ACF 300 of the both side surfaces of the chip stack structure CSS in the y direction, the conductive patterns 410 may extend in the z direction and may be arranged spaced apart from one another in the x direction. Also, positions of the conductive patterns 410 in the x direction may be substantially the same as x-direction positions of the chip pads 230 exposed at a side surface of a corresponding semiconductor chip 200. Also, as seen in FIG. 6E, in the conductive pattern film 400 attached on the ACF 300 of the both side surfaces of the chip stack structure CSS in the x direction, the conductive patterns 410 may extend in the z direction and may be arranged spaced apart from one another in the y direction. Also, positions of the conductive patterns 410 in the y direction may be substantially the same as y-direction positions of the chip pads 230 exposed at a side surface of a corresponding semiconductor chip 200.

In some implementations, at least some of the conductive patterns 410 of the conductive pattern film 400 may extend in a diagonal direction such as the x direction, the y direction, an x-z direction, or a y-z direction as well as the z direction, at the polymer film 420. In a case where the conductive patterns 410 extend in the x direction, the y direction, or a diagonal direction, the conductive patterns 410 may overlap each other, and, for example, an insulation layer may be disposed between the overlapping conductive patterns 410.

To describe in detail a process of attaching the conductive pattern film 400 on the ACF 300 with reference to FIGS. 7A and 7B, first, the conductive pattern film 400 may be aligned on a corresponding side surface of the chip stack structure CSS so that positions of the conductive patterns 410 correspond to positions of the chip pads 230 of the semiconductor chip 200. Subsequently, the conductive pattern film 400 may be attached on the ACF 300 of the corresponding side surface of the chip stack structure CSS by applying heat and pressure H-P. Adhesive resin 320 of the ACF 300 may have fluidity, based on the heat and pressure H-P, and thus, the conductive pattern 410 of the conductive pattern film 400 may be inserted into the adhesive resin 320 of the ACF 300. Also, conductive particles 310 of the ACF 300 may concentrate between the conductive pad 410 and the chip pad 230, and thus, a conductive path may be formed between the conductive pattern 410 and the chip pad 230 by using the conductive particles 310. Also, the same process may be performed on the ACF 300 on the package substrate 100, and thus, a conductive path (e.g., a localized conductive path based on the presence of the conductive patterns 410) may be formed between the conductive pattern 410 of the conductive pattern film 400 and the substrate pad 120 by using the conductive particles 310.

In FIGS. 7A and 7B, a process of attaching the ACF 300 and the conductive pattern film 400 on one side surface of the chip stack structure CSS is illustrated, but the same process can be performed on one or more other side surfaces of the chip stack structure CSS. For example, as illustrated in FIG. 6E, the ACF 300 and the conductive pattern film 400 may be attached on four side surfaces of the chip stack structure CSS and the upper surface of the package substrate 100.

Also, in FIGS. 6D and 6E, the ACF 300 may be attached on all of the four side surfaces of the chip stack structure CSS, and then, the conductive pattern film 400 may be attached on the ACF 300. However, in some implementations, the ACF 300 and/or the conductive pattern film 400 may be attached separately on separate side surfaces of the chip stack structure CSS. For example, the ACF 300 and the conductive pattern film 400 may be attached to each other at a first side surface of the chip stack structure CSS, and, subsequently, the ACF 300 and the conductive pattern film 400 may be attached to each other at a second side surface of the chip stack structure CSS.

Furthermore, in a case in which the ACF 300 and the conductive pattern film 400 are attached on each other at only one side surface of the chip stack structure CSS, the semiconductor package 1000a of FIG. 3A may be manufactured as a result of the process. Also, in a case where the ACF 300 and the conductive pattern film 400 are attached on each other at two side surfaces of the chip stack structure CSS, the semiconductor package 1000b of FIG. 4A may be manufactured as a result of the process.

After the conductive pattern film 400 is attached on the ACF 300, a sealant 500 may seal the chip stack structure CSS on the package substrate 100 through a molding process, and thus, the semiconductor package 1000 of FIG. 1 may be manufactured.

FIGS. 8A to 8H are cross-sectional views illustrating a process of preparing a semiconductor chip, e.g., a semiconductor chip of FIG. 6A. Descriptions which are the same as or similar to the descriptions of FIGS. 1 to 2D are briefly given or are omitted, and can equally apply to the elements of FIGS. 8A to 8H except where noted otherwise or suggested otherwise by context.

Referring to FIG. 8A, in a method of manufacturing a semiconductor package, according to some implementations, an active layer 220W and chip pads 230W may be first formed at an upper portion of a wafer 210W. The wafer 210W may include Si. However, a material of the wafer 210W is not limited to Si. Here, the active layer 220W may include an integrated circuit layer and a wiring layer. Descriptions of the integrated circuit layer and the wiring layer may be the same as the descriptions of the semiconductor package 1000 of FIG. 1.

A scribe lane 240 may be disposed at an upper portion of the wafer 210W. The scribe lane 240 may correspond to a boundary portion by which a plurality of semiconductor chips on the wafer 210W are differentiated from one another. Also, by removing the scribe lane 240 in the wafer 210W later, the semiconductor chips may be individualized/separated. The chip pads 230W may be formed to contact the scribe lane 240. The chip pads 230W may be disposed to contact the scribe lane 240, and then, by removing the scribe lane 240, the chip pads 230W may be exposed at a side surface of the semiconductor chip, for example, a side surface of the active layer 210W.

In FIG. 8A, the chip pads 230W may be disposed to contact one side surface of the scribe lane 240. As described above, in a case where the chip pads 230W are disposed to contact one side surface of the scribe lane 240, when the semiconductor chips are individualized later, the chip pads 230W may be exposed at only a side surface of a semiconductor chip corresponding to a corresponding scribe lane 240. However, by arranging the chip pads 230W in contact with all scribe lanes surrounding a semiconductor chip, when the wafer 210W is individualized into the semiconductor chips later, the chip pads 230W may be exposed at all of four side surfaces of the semiconductor chip.

Referring to FIG. 8B, after the active layer 220W and the chip pads 230W are formed in the wafer 210W, the wafer 210W may be reversed, and an exposed surface of the active layer 220W may be attached on supporting tape 600. For purposes of illustration, only the supporting tape 600 is illustrated, but the supporting tape 600 may be disposed on a carrier wafer and the wafer 210W may be disposed on the carrier wafer through the supporting tape 600 and may be supported by the carrier wafer.

Referring to FIG. 8C, subsequently, the wafer 210W may be thinned by removing a backside portion of the wafer 210W through a back-grinding process B-G. For example, in the back-grinding process B-G, a backside portion of the wafer 210W up to a portion of the scribe lane 240 may be removed. A portion of the wafer 210W after the back-grinding process B-G may configure a body layer of the semiconductor chip. For reference, in the wafer 210W, a surface of the active layer 220W may correspond to a front-side surface, and a surface opposite thereto may correspond to a backside surface.

Referring to FIG. 8D, subsequently, the wafer 210W may be detached from the supporting tape 600 and may be attached on a dicing tape 720 of a ring mount apparatus 700. The backside surface of the wafer 210W may be attached on the dicing tape 720. For reference, the ring mount apparatus 700 may be an apparatus that is used to individualize the wafer 210W into semiconductor chips and may include a ring mount frame 710 and the dicing tape 720. Also, the ring mount frame 710 may have a circular ring shape and may have a structure where the dicing tape 720 is attached on a lower side and the lower side is plugged by the dicing tape 720.

Referring to FIG. 8E, the wafer 210W may be attached on the dicing tape 720 of the ring mount apparatus 700, and then, protection tape 800 may be attached on an upper surface of the wafer 210W. The protection tape 800 may be referred to as protective layer coating (PLC). The protection tape 800 may prevent the active layer 220W and the chip pad 230W from being polluted or damaged in a process of removing the scribe lane 240.

Referring to FIG. 8F, the protection tape 800 may be attached on the wafer 210W, and then, the scribe lane 240 may be removed through a laser grooving process L-G. Laser grooving may be referred to as laser sawing. Also, as seen in FIG. 8F, the scribe lane 240 may not be completely removed through the laser grooving process L-G. Accordingly, a plasma dicing process P-D of FIG. 8G may be performed by completely removing the scribe lane 240.

In some implementations, when preparing the semiconductor chip, the laser grooving process L-G may be used for removing the scribe lane 240, but a process of removing the scribe lane 240 is not limited to the laser grooving process L-G. For example, the scribe lane 240 may be removed through a mechanical sawing process such as blade sawing.

Referring to FIG. 8G, after the scribe lane 240 is removed through the laser grooving process L-G, a remaining scribe lane 240 may be completely removed through the plasma dicing process P-D. The chip pads 230W may be exposed at a side surface of a corresponding semiconductor chip 200, based on the complete removal of the scribe lane 240.

For reference, the plasma dicing process P-D may denote a process which places the ring mount apparatus, including the wafer 210W, in a plasma chamber and removes the scribe lane 240 through a plasma process. In FIG. 8G, a portion surrounding the ring mount apparatus 700 including the wafer 210W may correspond to a portion, filled with plasma, of the plasma chamber.

Referring to FIG. 8H, subsequently, by removing the protection tape 800 on the upper surface of the wafer 210W, the wafer 210W may be individualized into semiconductor chips 200. Each of the semiconductor chips 200 may include a body layer 210, an active layer 220, and a chip pad 230. In some implementations, even after the protection tape 800 is removed, the semiconductor chips 200 may be maintained attached on the dicing tape 720 of the ring mount apparatus 700. Accordingly, subsequently, the semiconductor chips 200 can be detached from the dicing tape 720 through a die detachment process to become separated from one another, and can be mounted on a package substrate.

FIGS. 9A to 9C are diagrams illustrating an example of a process of forming an oxide bonding, in a process of stacking semiconductor chips, e.g., the semiconductor chips of FIG. 6C or other semiconductor chips 200 that are oxide-bonded to one another as described herein. Descriptions which are the same as or similar to the descriptions of FIGS. 1 to 2D are briefly given or are omitted, and can equally apply to the elements of FIGS. 9A to 9C except where noted otherwise or suggested otherwise by context.

Referring to FIG. 9A, a process of forming oxide bonds between semiconductor chips 200 may include performing plasma processing and then performing deionized (DI) water cleaning on the semiconductor chips 200 to form an OH dangling bond on the semiconductor chips 200. For example, each of the semiconductor chips 200 may include an oxide film 260 of SiO₂, formed on a lower surface of a body layer 210, and a passivation layer 235 of SiCN or SiN formed on an upper surface of an active layer 220. When plasma processing is performed on the semiconductor chips 200, as illustrated in FIG. 9A, the OH dangling bond may be formed in the oxide film 260 and the passivation layer 235. The oxide film 260 of SiO₂ may correspond to a natural oxide film. Furthermore, in some implementations, a polymer adhesive layer (e.g., 250a of FIG. 5B) may be attached on an upper surface or a lower surface of the semiconductor chip 200. In this case, plasma processing and DI water cleaning subsequent thereto may be performed on a polymer adhesive layer 250. Plasma processing and DI water cleaning subsequent thereto may be performed on each of the semiconductor chips 200, or may be performed on all of the semiconductor chips 200 by wafer units. Also, plasma processing and DI water cleaning on the semiconductor chips 200 may be performed on both of the oxide film 260 and the passivation layer 235, or may be performed on one of the oxide film 260 and the passivation layer 235.

Referring to FIG. 9B, after the OH dangling bond is formed in the semiconductor chips 200, an upper semiconductor chip may be stacked on a lower semiconductor chip. For example, a lower surface of a second semiconductor chip 200-2 (i.e., the oxide film 260) may be stacked to contact an upper surface of a first semiconductor chip 200-1 (i.e., the passivation layer 235). In a process of stacking the second semiconductor chip 200-2 on the first semiconductor chip 200-1, as illustrated in FIG. 9B, OH dangling bonds may form a hydrogen bonding H-D. The hydrogen bonding H-D may have a relatively low bonding force. Accordingly, the hydrogen bonding H-D may have a bonding force which enables the second semiconductor chip 200-2 to be maintained on the first semiconductor chip 200-1.

Referring to FIG. 9C, after the hydrogen bonding H-D is formed by stacking the second semiconductor chip 200-2 on the first semiconductor chip 200-1, high-temperature annealing may be performed. The hydrogen bonding H-D may be changed to an oxide bonding O-D, based on the high-temperature annealing. For example, in a case which is simply expressed as a chemical formula, the hydrogen bonding H-D may be changed to “—OH+—OH-->O+H₂O”, based on the high-temperature annealing. Here, a process temperature of the high-temperature annealing may be about 150° C. or more. However, the high-temperature annealing is not limited to that temperature range. The oxide bonding O-D may have a bonding force which is higher than the hydrogen bonding H-D. Accordingly, the second semiconductor chip 200-2 may be solidly maintained on the first semiconductor chip 200-1 with a high bonding force.

Above, examples have been described in the drawings and the specification. It will be understood by those of ordinary skill in the art that various modifications may be implemented without departing from the scope of this disclosure.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While examples have been particularly shown and described, it will be understood that various changes in form and details may be made therein without departing from the spirit and scope of the following claims.

1. A semiconductor package comprising:
a package substrate;
a chip stack structure including at least two semiconductor chips aligned with one another and stacked on the package substrate in a vertical direction, each semiconductor chip of the at least two semiconductor chips having a side surface and including chip pads arranged at the side surface;
an anisotropic conductive film (ACF) covering a side surface of the chip stack structure; and
a conductive pattern film covering the ACF and including a conductive pattern electrically connecting the chip pads to a substrate pad of the package substrate.

2. The semiconductor package of claim 1, wherein the chip pads are arranged at one or more of four side surfaces of the at least two semiconductor chips, and
wherein the ACF and the conductive pattern film cover one or more side surfaces of the chip stack structure, corresponding to the one or more of the four side surfaces of the at least two semiconductor chips at which the chip pads are arranged.

3. The semiconductor package of claim 1, wherein the chip pads are arranged at four side surfaces of the at least two semiconductor chips, and
wherein the ACF and the conductive pattern film cover four side surfaces of the chip stack structure.

4. The semiconductor package of claim 3, wherein the ACF and the conductive pattern film extend in the vertical direction on each of the four side surfaces of the chip stack structure, are curved by 90 degrees at positions at which the chip stack structure is bonded to the package substrate, and extend in a first horizontal direction or a second horizontal direction on the package substrate, wherein the second horizontal direction is perpendicular to the first horizontal direction.

5. The semiconductor package of claim 4, wherein the conductive pattern extends on each of the four side surfaces of the chip stack structure to electrically connect, with each other, corresponding chip pads of the at least two semiconductor chips, and extend in the first horizontal direction or the second horizontal direction on the package substrate to electrically connect the chip pads of the at least two semiconductor chips to the substrate pad.

6. The semiconductor package of claim 4, wherein:
at a first side of the chip stack structure, the conductive pattern film extends in the first horizontal direction on the package substrate, and the conductive pattern of the conductive pattern film comprises first multiple conductive patterns that are spaced apart from each other on a corresponding side surface of the chip stack structure in the second horizontal direction; and
at a second side of the chip stack structure, the conductive pattern film extends in the second horizontal direction on the package substrate, and the conductive pattern of the conductive pattern film comprises second multiple conductive patterns spaced apart from each other on a corresponding side surface of the chip stack structure in the first horizontal direction.

7. The semiconductor package of claim 1, wherein the conductive pattern is electrically connected to the chip pads or the substrate pad through conductive particles of the ACF.

8. The semiconductor package of claim 1, wherein the at least two semiconductor chips comprise a first semiconductor chip that is lowermost and a second semiconductor chip on the first semiconductor chip,
wherein the first semiconductor chip is bonded to the package substrate by an adhesive layer, and
wherein the second semiconductor chip is bonded to the first semiconductor chip through oxide bonding.

9. The semiconductor package of claim 8, wherein the oxide bonding is formed between a SiCN layer or a SiN layer of an upper surface of the first semiconductor chip and a SiO₂ layer of a lower surface of the second semiconductor chip, or is formed using a polymer adhesive layer disposed between the first semiconductor chip and the second semiconductor chip.

10. The semiconductor package of claim 1, wherein the at least two semiconductor chips comprise a first semiconductor chip that is lowermost and a second semiconductor chip on the first semiconductor chip,
wherein the first semiconductor chip is bonded to the package substrate by a first adhesive layer, and
wherein the second semiconductor chip is bonded to the first semiconductor chip by a a second adhesive layer.

11. The semiconductor package of claim 1, comprising a sealant covering the side surface and an upper surface of the chip stack structure.

12. A semiconductor package comprising:
a package substrate including a substrate pad disposed on an upper surface of an outer portion of the package substrate;
a chip stack structure including at least two semiconductor chips aligned with one another and stacked on a center portion of the package substrate in a vertical direction,
wherein each semiconductor chip of the at least two semiconductor chips includes a body layer at a lower portion of the semiconductor chip, an active layer at an upper portion of the semiconductor chip, a side surface of the active layer, and chip pads arranged at the side surface of the active layer;
an anisotropic conductive film (ACF) covering a side surface of the chip stack structure and the substrate pad on the package substrate, the ACF including adhesive resin and conductive particles; and
a conductive pattern film including a polymer film and a conductive pattern on the polymer film, wherein the conductive pattern film covers the ACF such that the chip pads are electrically connected to the substrate pad through the conductive pattern.

13. The semiconductor package of claim 12, wherein the chip pads are arranged at four side surfaces of the active layer of each semiconductor chip of the at least two semiconductor chips,
wherein the ACF and the conductive pattern film cover four side surfaces of the chip stack structure, and
wherein the ACF and the conductive pattern film extend in the vertical direction on each of the four side surfaces of the chip stack structure, are curved by 90 degrees at positions at which the chip stack structure is bonded to the package substrate, and extend in a first horizontal direction or a second horizontal direction on the package substrate, wherein the second horizontal direction is perpendicular to the first horizontal direction.

14. The semiconductor package of claim 13, wherein the conductive pattern is electrically connected to the chip pads or the substrate pad by the conductive particles,
wherein the conductive pattern extends on each of the four side surfaces of the chip stack structure to electrically connect, with each other, corresponding chip pads of the at least two semiconductor chips, and extend in the first horizontal direction or the second horizontal direction on the package substrate to electrically connect the chip pads of the at least two semiconductor chips to the substrate pad, and
wherein the conductive pattern comprises multiple conductive patterns that are spaced apart from each other on each of the four side surfaces of the chip stack structure in the first horizontal direction or the second horizontal direction.

15. The semiconductor package of claim 12, wherein a first semiconductor chip that is lowermost of the at least two semiconductor chips is bonded to the package substrate by an adhesive layer, and
wherein a second semiconductor chip of the at least two semiconductor chips is bonded to the first semiconductor chip through oxide bonding or a second adhesive layer.

16. The semiconductor package of claim 15, wherein the second semiconductor chip is bonded to the first semiconductor chip through oxide bonding, and
wherein the oxide bonding is formed between a SiCN layer or a SiN layer of an upper surface of an active layer of the first semiconductor chip and a SiO₂ layer of a lower surface of a body layer of the second semiconductor chip, or is formed by using a polymer adhesive layer disposed between the first semiconductor chip and the second semiconductor chip.

17. A semiconductor package comprising:
a package substrate;
a chip stack structure including at least two semiconductor chips aligned with one another and stacked on the package substrate in a vertical direction, each semiconductor chip of the at least two semiconductor chips having four side surface and including chip pads arranged at the four side surfaces;
an anisotropic conductive film (ACF) covering four side surfaces of the chip stack structure and a portion of an upper surface of the package substrate;
a conductive pattern film covering the ACF and including a conductive pattern electrically connecting the chip pads to a substrate pad of the package substrate; and
a sealant covering a side surface and an upper surface of the chip stack structure.

18. The semiconductor package of claim 17, wherein the ACF and the conductive pattern film extend in the vertical direction on each of the four side surfaces of the chip stack structure, are curved by 90 degrees at positions at which the chip stack structure is bonded to the package substrate, and extend in a first horizontal direction or a second horizontal direction on the package substrate, wherein the second horizontal direction is perpendicular to the first horizontal direction.

19. The semiconductor package of claim 18, wherein the conductive pattern is electrically connected to the chip pads or the substrate pad by conductive particles of the ACF, and
wherein the conductive pattern extends on each of the four side surfaces of the chip stack structure to electrically connect, with each other, corresponding chip pads of the at least two semiconductor chips, and extend in the first horizontal direction or the second horizontal direction on the package substrate to connect the chip pads to the substrate pad.

20. The semiconductor package of claim 17, wherein the at least two semiconductor chips comprise a first semiconductor chip that is lowermost and a second semiconductor chip on the first semiconductor chip,
wherein the first semiconductor chip is bonded to the package substrate by an adhesive layer, and
wherein the second semiconductor chip is bonded to the first semiconductor chip through oxide bonding.

21-26. (canceled)
